(19) United States
(12) Patent Application Publication
(10) Pub. No.: US 2013/0043773 A1
(43) Pub. Date: Feb. 21, 2013

(54) BEZEL ASSEMBLY FOR ELECTRONIC DEVICE

(71) Applicant: YUN-LUNG CHEN, Tu-Cheng (TW)

(72) Inventor: YUN-LUNG CHEN, Tu-Cheng (TW)

(73) Assignee: HON HAI PRECISION INDUSTRY CO., LTD., Tu-Cheng (TW)

(21) Appl. No.: 13/444,062

(22) Filed: Apr. 11, 2012

(30) Foreign Application Priority Data
Aug. 15, 2011 (CN) 201110232278.8

(51) Int. Cl. H05K 5/02

(52) U.S. Cl. 312/223.1

(57) ABSTRACT

A bezel assembly includes a panel, a shielding member attached to the panel, and a securing member. The panel defines a hole. The shielding member includes a mounting portion. The securing member includes a securing panel and a resilient arm. A first end of the resilient arm is connected to the securing panel, and a second end of the resilient arm is attached to the panel. The mounting portion extends through the hole and engages with the securing panel. When the shielding member is disengaged from the panel, the securing panel is moved relative to the panel in a direction substantially parallel to the shielding member, the resilient arm is deformed, the securing panel is disengaged from the mounting portion, and the mounting portion is removed from the panel in a direction substantially perpendicular to the shielding member.

### BACKGROUND

1. Technical Field

The present disclosure relates to electronic device enclosures, more particularly to a bezel assembly.

2. Description of Related Art

A panel of a computer case often includes an opening for an optical disk drive to move in or out of the computer case. A decorating plate and a shielding plate are used to shield the opening. Usually, the decorating plate is secured to an interior of the shielding plate using clipping members. When the shielding plate needs to be maintained or disassembled, the clipping members are disengaged from the decorating plate after the decorating plate is disengaged from the computer case. The dissembling processes may be is laborious and time consuming. Therefore, an improved bezel assembly may be desired within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a bezel assembly in accordance with an embodiment.

FIG. 2 is similar to FIG. 1, showing a different aspect.

FIG. 3 is an isometric view of a securing member of the bezel assembly in accordance with an embodiment.

FIG. 4 is an assembled view to FIG. 1.

FIG. 5 is a side view of FIG. 4.

FIG. 6 is similar to FIG. 5, showing in a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

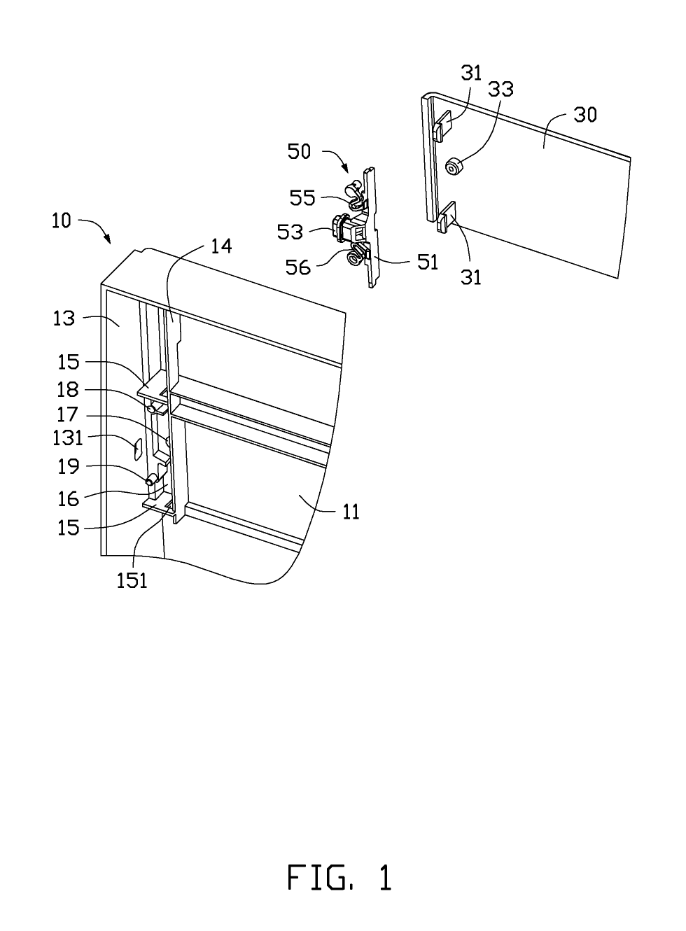

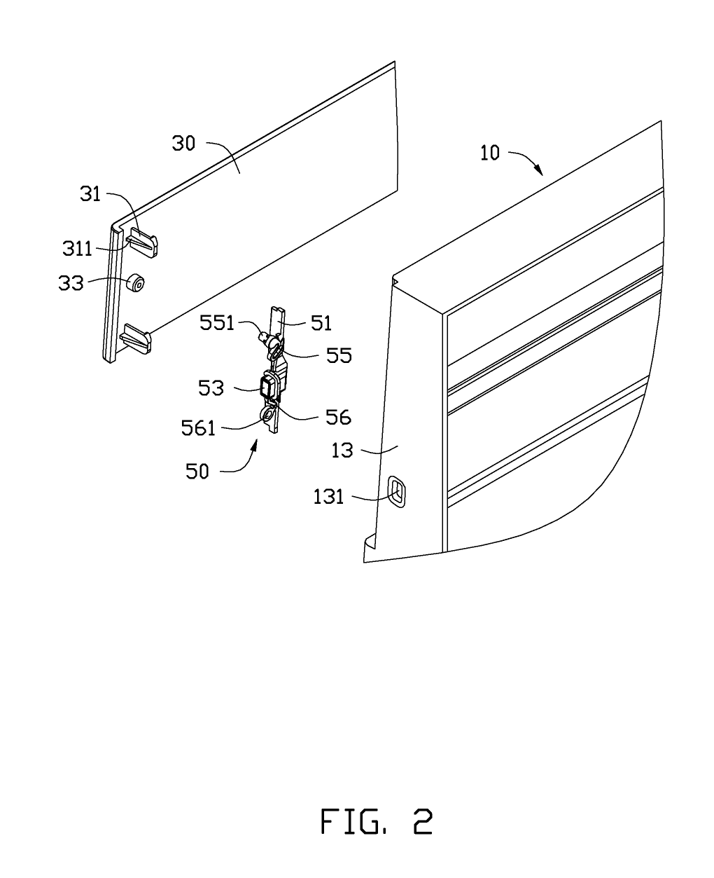

FIGS. 1 and 2, show a bezel assembly in accordance with an embodiment including a panel 10, a shielding member 30, and a securing member 50 attached to the panel 10. In one embodiment, the panel 10 is a decorating panel of a computer case.

The panel 10 defines an opening 11 for receiving an optical disk drive, and the panel 10 includes a flange 13 and a positioning panel 14 adjacent to the flange 13. The flange 13 defines a through hole 131. Two connecting panels 15 are connected to the flange 13 and the positioning panel 14. In one embodiment, each of the two connecting panels 15 is substantially perpendicular to the flange 13. A sliding slot 151 is defined in each of the two connecting panels 15 adjacent to the positioning panel 14. Two holes 16 and a positioning hole 17 are defined in the panel 10. Each of the two holes 16 is adjacent to each of the two connecting panels 15, and the positioning hole 17 is located between the two holes 16. A receiving hole 18 is defined adjacent to one of the two connecting panels 15. A protruding post 19, is located adjacent to another one the two connecting panels 15. In one embodiment, the sliding slot 151 communicates with each of the two holes 16.

The shielding member 30 includes two mounting portions 31 and a positioning post 33 located between the two mounting portions 31. A strengthening rib 311 extends from each of the two mounting portions 31. In one embodiment, each of the two mounting portions 31 is a hook, and substantially perpendicular to the shielding member 30.

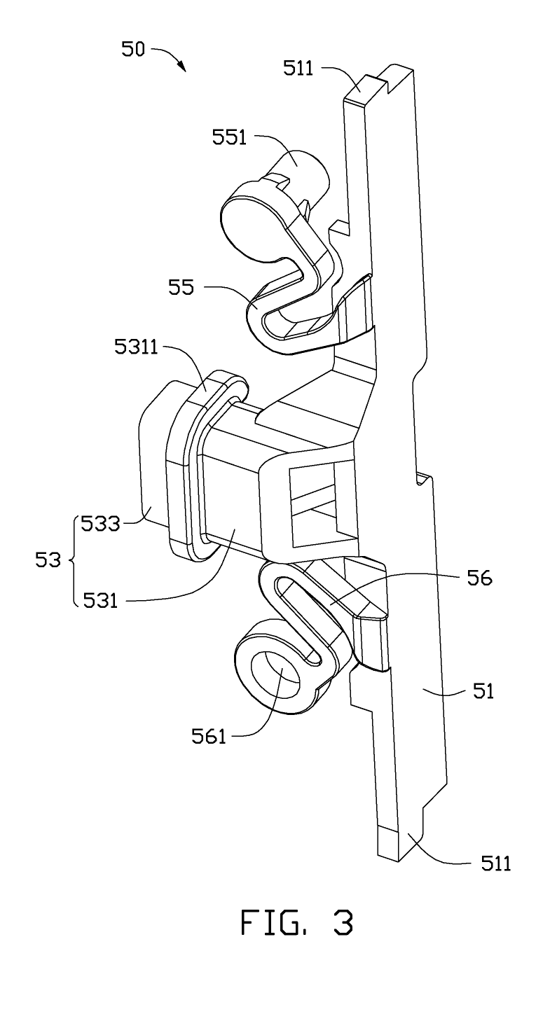

Referring to FIG. 3, the securing member 50 can be located between the flange 13 and the positioning panel 14, and includes a securing panel 51, an operating portion 53 connected to the securing panel 51, a first resilient arm 55, and a second resilient arm 56. The first resilient arm 55 and the second resilient arm 56 are located on opposite sides of the operating portion 53. In one embodiment, the first resilient arm 55 and the second resilient arm 56 are crooked, a free end of the first resilient arm 55 is circular, and a free end of the second resilient arm 56 is also circular.

Two inserting portions 511 extend from opposite ends of the securing panel 51, corresponding to each of the sliding slot 151. The operating portion 53 includes a connecting portion 531 and a button 533 connected to the connecting portion 531. The connecting portion 531 includes a limiting portion 5311. In one embodiment, a size of the limiting portion 5311 is greater than that of the through hole 131, and a size of the button 533 is less than that of the through hole 131. A securing post 551 extends from a free end of the first resilient arm 55, and a securing hole 561 is defined in a free end of the second resilient arm 56. In one embodiment, the first resilient arm 55 and the second resilient arm 56 are not limited to such a configuration and the configuration can be changed according to other known techniques, such as two securing posts extending from the first and the second resilient arms 55, 56, respectively. Two receiving holes can be defined in the panel 10 to receive the securing posts. Alternatively, two securing holes are defined in the first and the second resilient arms 55, 56, respectively, and two protruding posts can be located on the panel 10 to engage in the securing holes. In one embodiment, the first and the second resilient arms 55, 56 can be two extension springs.

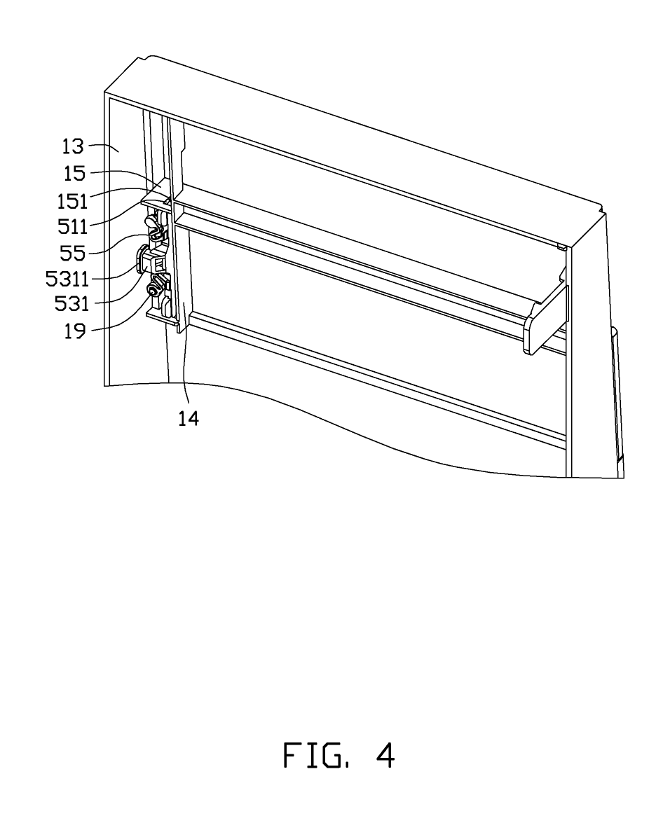

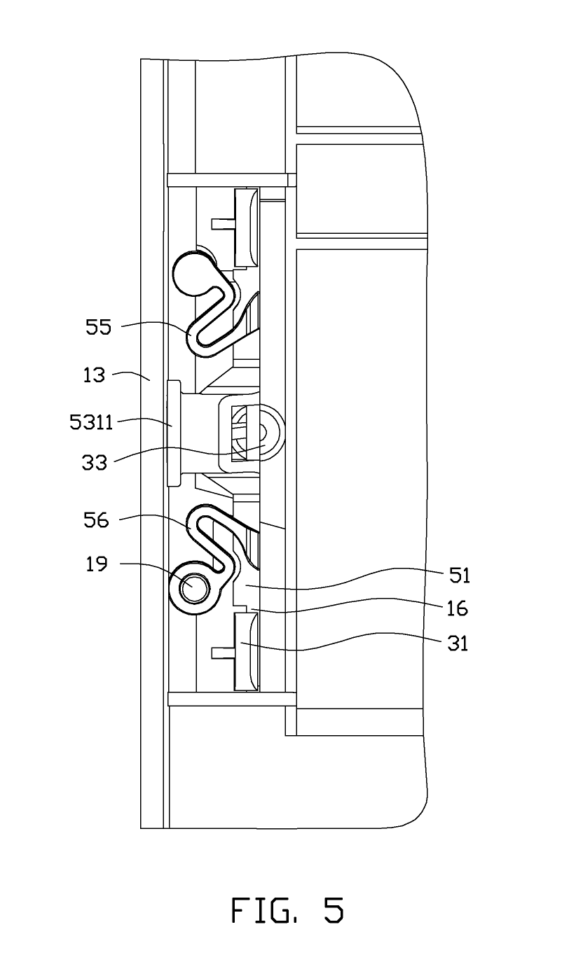

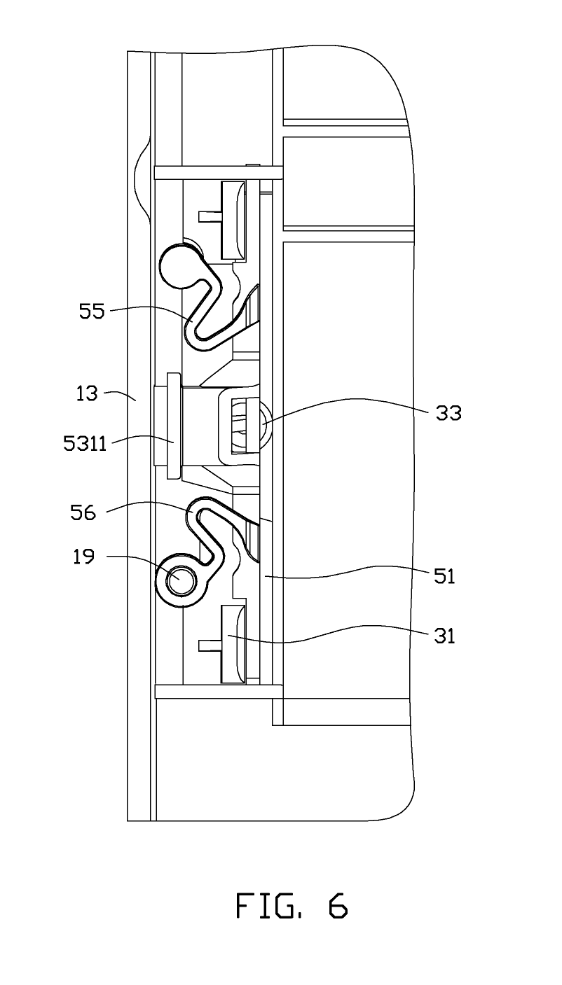

Referring to FIGS. 4-6, in assembly, the securing member 50 is located between the flange 13 and the positioning panel 14. The securing panel 51 abuts the two connecting panels 15, and the button 533 abuts the flange 13. The securing post 551 is aligned with the receiving hole 18, and the securing hole 561 is aligned with the protruding post 19. The securing member 50 is pressed to deform the two connecting panels 15 in a direction away from the securing panel 51. When the securing panel 51 extends through the two connecting panels 15 and the two inserting portions 511 are received in each of the sliding slot 151, the two connecting panels 15 are released. The securing panel 51 is thus secured to the two connecting panels 15. Synchronously, the flange 13 is deformed by the button 533, and released when the button 533 extends through the through hole 131. The securing member 50 is thus secured to the flange 13 and positioning panel 14. In an original state, each of the two inserting portions 511 is located a first end of each of the sliding slot 151, and the first end of the each of the sliding slot 151 is away from the positioning panel 14. The shielding member 30 abuts the panel 10, and the two mounting portions 31 extend through the two holes 16 and clipped to the securing panel 51. The positioning post 33 is engaged in the positioning hole 17, and the shielding member 30 is thus secured to the panel 10.

In disassembly, the button 533 is pressed to move the securing member 50 in a direction towards the positioning panel 14 and substantially parallel to the shielding member 30. Each of the two inserting portions 511 is slid to a second end of each of the sliding slot 151 opposite to the first end. The securing panel 51 is moved away from the two mounting portions 31, and deforms the first and the second resilient arms 55, 56. The shielding member 30 is moved away form the panel 10 in a direction substantially perpendicular to the shielding member 30. The positioning post 33 is disengaged from the positioning hole 17, and the shielding member 30 can be detached from the panel 10. The button 533 is released, and the first and the second resilient arms 55, 56 are released.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A bezel assembly comprising:
a panel defining a hole;
a shielding member attached to the panel and comprising a mounting portion; and
a securing member comprising a securing panel and a resilient arm; the resilient arm comprising a first end and a second end opposite to the first end; the first end being connected to the securing panel, and the second end being attached to the panel;
wherein the mounting portion extends through the hole and engages with the securing panel, and
wherein to disengage the shielding member from the panel, firstly the securing panel is moved relative to the panel in a direction substantially parallel to the shielding member so that the resilient arm is deformed and that the securing panel is disengaged from the mounting portion, and secondly the mounting portion is removed from the panel in a direction substantially perpendicular to the shielding member.

2. The bezel assembly of claim 1, wherein the resilient arm is crooked, and the resilient arm is configured to be deformed by stretching.

3. The bezel assembly of claim 1, wherein the panel comprises a flange and a positioning panel adjacent to the flange, and both the securing panel and the resilient arm are located between the flange and the positioning panel.

4. The bezel assembly of claim 3, wherein the panel further comprises a connecting panel connected to the flange and to the positioning panel, the connecting panel defines a sliding slot, and an inserting portion extends from a free end of the securing panel, the inserting portion is configured to slidably engage in the sliding slot.

5. The bezel assembly of claim 4, wherein the connecting panel is substantially perpendicular to the positioning panel and the flange.

6. The bezel assembly of claim 5, wherein the securing member further comprises an operating portion connected to the securing panel, and the operating portion is configured to extend out of the flange.

7. The bezel assembly of claim 6, wherein the operating portion comprises a connecting portion connected to the securing panel and a button connected to the connecting portion, the button extending out of the flange, and the connecting portion comprising a limiting portion abutting an inner surface of the flange.

8. The bezel assembly of claim 6, wherein the panel comprising a receiving hole, and a securing post extends from the second end of the resilient arm, the securing post is configured to engage in the receiving hole.

9. The bezel assembly of claim 1, wherein the shielding member comprises a positioning post, and the panel defines a positioning hole, the positioning post is configured to be received in the positioning hole.

10. A bezel assembly comprising:
a panel defining a hole and comprising a flange and a positioning panel;
a shielding member attached to the panel and comprising a mounting portion; and
a securing member located between the flange and the positioning panel, the securing member comprising a securing panel, and two resilient arms; each of the two resilient arms comprising a first end and a second end opposite to the first end; the first end being connected to the securing panel, and the second end being attached to the panel;
wherein the mounting portion be configured to extend through the hole and to engage with the securing panel, and the securing panel is configured to be moved relative to the panel in a direction substantially parallel to the shielding member, and
wherein to disengage from the mounting portion from the securing panel, the two resilient arms are deformed so that the mounting portion is removed from the panel in a direction substantially perpendicular to the shielding member.

11. The bezel assembly of claim 10, wherein each of the two resilient arm is crooked, and the each of the two resilient arm is configured to be deformed by stretching.

12. The bezel assembly of claim 10, wherein each of the two resilient arms is an extension spring.

13. The bezel assembly of claim 10, wherein the panel further comprises a connecting panel connected to the flange and to the positioning panel, the connecting panel defines a sliding slot, and an inserting portion extends from a free end of the securing panel, the inserting portion is configured to slidably engage in the sliding slot.

14. The bezel assembly of claim 13, wherein the connecting panel is substantially perpendicular to the positioning panel and the flange.

15. The bezel assembly of claim 10, wherein the securing member further comprises an operating portion connected to the securing panel, each of the two resilient arms is located on an opposite side of the operating portion, and the operating portion is configured to extend out of the flange.

16. The bezel assembly of claim 15, wherein the operating portion comprises a connecting portion connected to the securing panel and a button connected to the connecting portion, the button extending out of the flange, and the connecting portion comprising a limiting portion abutting an inner surface of the flange.

17. The bezel assembly of claim 15, wherein the panel comprising a receiving hole, and a securing post extends from the second end of each of the two resilient arms, the securing post is configure to engage in the receiving hole.

18. The bezel assembly of claim 10, wherein the shielding member comprises a positioning post, and the panel defines a positioning hole, the positioning post is configure to be received in the positioning hole.
